(19) United States
(12) Patent Application Publication
(10) Pub. No.: US 2026/0088063 A1
(43) Pub. Date: Mar. 26, 2026

(54) VOLTAGE GENERATING CIRCUITS HAVING ENHANCED PULL-UP AND PULL-DOWN CONTROL AND NONVOLATILE MEMORY DEVICES INCLUDING THE SAME

(71) Applicant: Samsung Electronics Co., Ltd., Suwon-si (KR)

(72) Inventors: Han Seul Kim, Suwon-si (KR); Jang Hwan Kim, Suwon-si (KR); Sung Ho Moon, Suwon-si (KR); Doo Hyun Shon, Suwon-si (KR)

(21) Appl. No.: 19/228,825

(22) Filed: Jun. 5, 2025

(30) Foreign Application Priority Data
Sep. 25, 2024 (KR) 10-2024-0129881

(51) Int. Cl. G11C 5/14

(52) U.S. Cl. CPC G11C 5/146

(57) ABSTRACT

A voltage generating circuit includes: an analog voltage generating circuit having a first amplifier therein, which is configured to generate an output voltage in response to a first reference voltage and a feedback voltage, and first and second digital driving circuits. The first digital driving circuit is configured to selectively provide a pull-up voltage boost to the output voltage generated by the first amplifier, in response to comparing the feedback voltage to a second reference voltage having a magnitude less than the first reference voltage by a first offset voltage. The second digital driving circuit is configured to selectively provide a pull-down voltage boost to the output voltage generated by the first amplifier, in response to comparing the feedback voltage to a third reference voltage having a magnitude greater than the first reference voltage by a second offset voltage.

### REFERENCE TO PRIORITY APPLICATION

This application claims priority under 35 U.S.C. 119 to Korean Patent Application No. 10-2024-0129881, filed Sep. 25, 2024, the disclosure of which is hereby incorporated herein by reference.

### BACKGROUND

The present disclosure relates to voltage generating circuits and nonvolatile memory devices including the same.

A voltage generating circuit may be used in various kinds of electronic devices such as nonvolatile memory devices, and is commonly used to provide a constant voltage. The rise time for an output voltage of the voltage generating circuit to reach a target voltage may be increased due to a capacitive load that is present at an output terminal of the voltage generating circuit. For high-speed operation of the electronic devices, research into techniques for reducing a stabilization time of the voltage generating circuit is ongoing.

### SUMMARY

An object of the present disclosure is to provide a voltage generating circuit capable of reducing a stabilization time.

Another object of the present disclosure is to provide a nonvolatile memory device including a voltage generating circuit capable of reducing a stabilization time.

According to some embodiments of present disclosure, there is provided a voltage generating circuit having an analog voltage generating circuit therein, which includes a first amplifier that generates an output voltage based on a first reference voltage and a feedback voltage, and first and second digital driving circuits for adjusting the output voltage. The first digital driving circuit may include: a second amplifier comparing a second reference voltage subtracted from the first reference voltage by a first offset with the feedback voltage, and outputting a first enable signal based on the compared result, and a first pump circuit increasing the output voltage in accordance with the first enable signal. The second digital driving circuit may include: a third amplifier comparing a third reference voltage added to the first reference voltage by a second offset with the feedback voltage and outputting a second enable signal based on the compared result, and a second pump circuit decreasing the output voltage in accordance with the second enable signal.

According to some embodiments, a voltage generating circuit is provided, which includes a reference voltage generating circuit receiving a first digital signal and generating a first reference voltage based on the first digital signal, a first amplifier receiving the first reference voltage and a feedback voltage and generating an output voltage, a first digital driving circuit comparing the feedback voltage with a second reference voltage subtracted from the first reference voltage by a first offset and increasing the output voltage in accordance with the compared result, and a pump control circuit adjusting increasing intensity of the first digital driving circuit based on the first digital signal and a second digital signal.

According to additional embodiments, a nonvolatile memory device is provided, which includes: a memory cell array having a plurality of memory cells for storing data, a control logic circuit controlling the memory cell array, and a voltage generator including an analog voltage generating circuit generating a voltage required for an operation of the memory cell array and a first digital driving circuit adjusting an output voltage of the analog voltage generating circuit. The control logic circuit provides the voltage generator with a first digital signal corresponding to a second operation subsequent to a first operation of the memory cell array, the analog voltage generating circuit provides the memory cell array with an output voltage required for the second operation based on a first reference voltage corresponding to the first digital signal and a feedback voltage, and the first digital driving circuit compares a second reference voltage subtracted from the first reference voltage by a first offset with the feedback voltage and increases the output voltage in accordance with the compared result.

The objects of the present disclosure are not limited to those mentioned above and additional objects of the present disclosure, which are not mentioned herein, will be clearly understood by those skilled in the art from the following description of the present disclosure.

### BRIEF DESCRIPTION OF THE DRAWINGS

FIG. 1 is a circuit view illustrating a voltage generating circuit.

FIG. 2 is a graph illustrating changes of an output voltage and a feedback voltage according to a time change in the voltage generating circuit of FIG. 1.

FIG. 3 is a circuit view illustrating a voltage generating circuit according to some embodiments.

FIG. 4 is a circuit view illustrating a voltage generating circuit according to some embodiments.

FIG. 5 is a block diagram illustrating an operation of a pump control circuit.

FIG. 6 is a block diagram illustrating an operation of a pump control circuit.

FIG. 7 is a circuit view illustrating a voltage generating circuit according to some embodiments.

FIG. 8 is a graph illustrating a change in a feedback voltage of a voltage generating circuit according to some embodiments.

FIG. 9 is a graph illustrating a change in an output voltage of a voltage generating circuit according to some embodiments.

FIG. 10 is a graph illustrating a change in a feedback voltage of a voltage generating circuit according to some embodiments.

FIG. 11 is a graph illustrating a change in an output voltage of a voltage generating circuit according to some embodiments.

FIG. 12 is a block diagram illustrating a nonvolatile memory device to which a voltage generating circuit according to some embodiments is applied.

FIG. 13 is a block diagram illustrating a storage device that includes the nonvolatile memory device of FIG. 12.

### DETAILED DESCRIPTION OF EMBODIMENTS

Hereinafter, the embodiments according to the technical spirits of the present disclosure will be described with reference to the accompanying drawings.

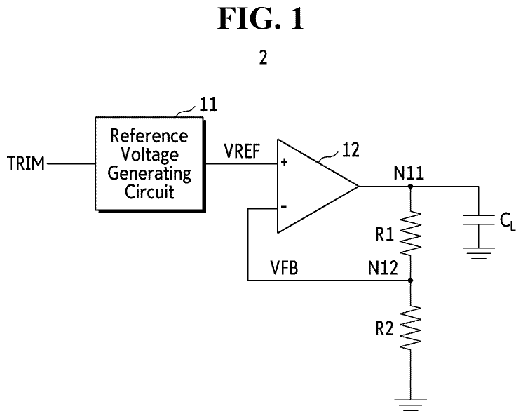

Referring to FIG. 1, a voltage generating circuit 2 may include a reference voltage generating circuit 11 and a first amplifier 12. The reference voltage generating circuit 2 may include, for example, a digital-to-analog converter DAC. The reference voltage generating circuit 2 may receive a first digital signal TRIM and generate a first reference voltage VREF based on the first digital signal TRIM. The first digital signal TRIM may be, for example, an n-bit (n is a natural number) digital code, and the first reference voltage VREF may be an analog voltage having a predetermined magnitude that is a function of the value of the first digital signal TRIM (e.g., a function of the n-bit digital code).

The first amplifier 12 may receive the first reference voltage VREF, which is provided by the reference voltage generating circuit 11, and a feedback voltage VFB (at respective + and − input terminals), and may generate an output voltage at an output node N11 thereof, which is electrically connected to a terminal of a load (e.g., capacitor C_{L}). The output node N11 may be connected to a feedback node N12 through a first resistor R1; and the feedback node N12 may be connected to a ground reference voltage terminal through a second resistor R2. As will be understood by those skilled in the art, the totem pole arrangement of the first and second resistors R1, R2 operates as a voltage divider; thus, a magnitude of the feedback voltage VFB formed at the feedback node N12 may be determined by the first resistor R1 and the second resistor R2.

The first amplifier 12 may generate the output voltage by using the first reference voltage VREF, and may receive the feedback voltage VFB generated by the output voltage to adjust the output voltage. A portion of the voltage generating circuit 2 may be implemented as, for example, a low-dropout (LDO) regulator. When a portion of the voltage generating circuit 2 is implemented as an LDO regulator, the voltage generating circuit 2 may further include a transistor connecting an external voltage with the output node N11, and the output terminal of the first amplifier 12 may be connected to a gate terminal of the transistor. However, the voltage generating circuit 2 is not limited to being implemented as the LDO regulator.

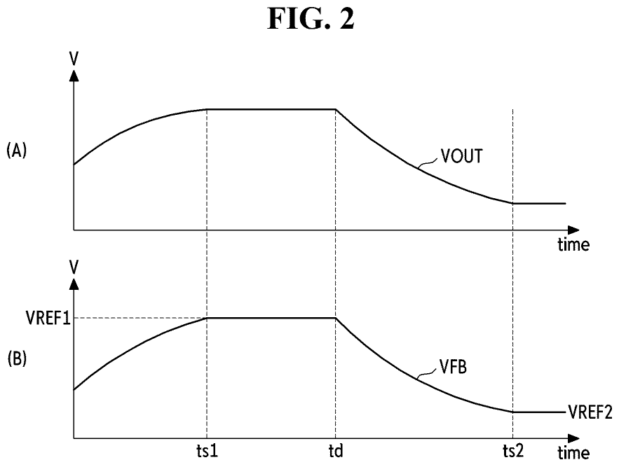

FIG. 2 is a graph illustrating changes of an output voltage and a feedback voltage according to a time change in the voltage generating circuit of FIG. 1. Graph (A) of FIG. 2 illustrates a change of an output voltage according to a time change, and graph (B) of FIG. 2 illustrates a change of a feedback voltage according to a time change. X-axis of two graphs represents a time change, and Y-axis of the two graphs represents a change in magnitude of a voltage. Due to capacitive load C_{L} present at the output node N11 of the voltage generating circuit 2, there is a “lag” time (hereinafter, referred to as a stabilization time) required for the output voltage to reach a target voltage. As will be understood by those skilled in the art, the greater the magnitude of the capacitor C_{L} within the load, the longer the stabilization time may be.

Referring to graph (A) of FIG. 2, it may take time from t=0 (t is a time) to t=ts1 until an output voltage VOUT is boosted to reach a first target voltage, and it may take time from t=td to t=ts2 until the output voltage VOUT is pulled down at a certain rate to reach a second target voltage. Referring to graph (B) of FIG. 2, when the feedback voltage VFB becomes equal to the reference voltage VREF1 or VREF2 for determining the target voltage, the output voltage reaches the target voltage. Accordingly, it may take time from t=0 to t=ts1 until the feedback voltage VFB is boosted at a certain rate to reach the reference voltage VREF1, and it may take time from t=td to t=ts2 until the feedback voltage VFB is pulled down at a certain voltage to reach another reference voltage VREF2. To achieve a high-speed operation of an electronic device in which the voltage generating circuit 2 is used, it is necessary to reduce a duration of the stabilization time.

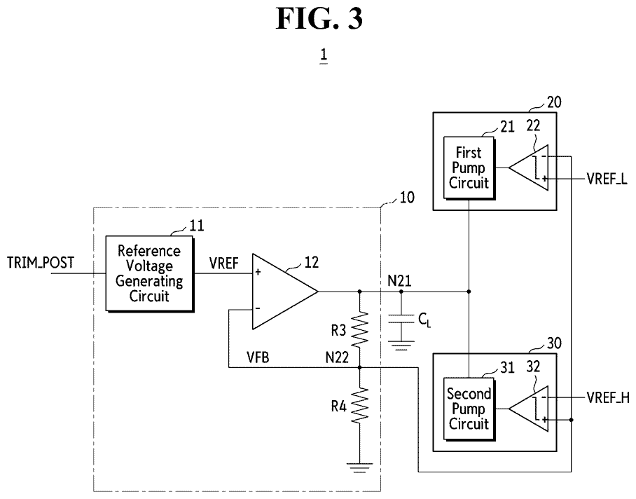

FIG. 3 is a circuit view illustrating a voltage generating circuit 1 according to some embodiments. As shown, the voltage generating circuit 1 may include an analog voltage generating circuit 10, a first digital driving circuit 20, and a second digital driving circuit 30. The analog voltage generating circuit 10 may include a reference voltage generating circuit 11 and a first amplifier 12. The reference voltage generating circuit 11 may be implemented as, for example, a digital-to-analog converter. The reference voltage generating circuit 11 may receive a first digital signal TRIM_POST and generate a first reference voltage VREF based on the received digital signal TRIM_POST. The first digital signal TRIM_POST may be, for example, an n-bit (n is a natural number) digital code, and the first reference voltage VREF may be an analog voltage having a predetermined magnitude. The reference voltage VREF may be continuously changed depending on the received digital signal/code.

The first amplifier 12 may receive the first reference voltage VREF, which is provided by the reference voltage generating circuit 11, and the feedback voltage VFB, and may generate an output voltage at an output node N21 of the first amplifier 12. The output node N21 may be connected to a feedback node N22 through a first resistor R3. The feedback node N22 may be connected to a power ground terminal through a second resistor R4. The magnitude of the feedback voltage VFB formed at the feedback node N22 may be determined by the totem pole arrangement of the first resistor R3 and the second resistor R4, which operates as a voltage divider. The first amplifier 12 may generate an output voltage by using the first reference voltage VREF, and may adjust the output voltage by receiving the feedback voltage VFB generated by the output voltage. A portion of the analog voltage generating circuit 10 may be implemented as, for example, a low-dropout (LDO) regulator. When a portion of the analog voltage generating circuit 10 is implemented as the LDO regulator, the analog voltage generating circuit 10 may further include a transistor that connects an external voltage with the output node N21, and the output terminal of the first amplifier 12 may be connected to a gate terminal of the transistor. However, the analog voltage generating circuit 10 is not limited to being implemented as the LDO regulator.

An output terminal of the first digital driving circuit 20 may be connected to the output node N21 of the first amplifier 12. The first digital driving circuit 20 may receive the feedback voltage VFB and a second reference voltage VREF_L and adjust the output voltage based on the feedback voltage VFB and the second reference voltage VREF_L. The first digital driving circuit 20 may include a first pump circuit 21 and a second amplifier 22.

The second amplifier 22 may compare the feedback voltage VFB with the second reference voltage VREF_L. The second reference voltage VREF_L may be a voltage (VREF_{L}=VREF−Voffset1) subtracted from the first reference voltage VREF by a first offset. The second amplifier 22 may output a first enable signal for controlling the first pump circuit 21. For example, the first enable signal may turn on or off the first pump circuit 21. In detail, the first enable signal may turn on the first pump circuit 21 while the second reference voltage VREF_L is higher than the feedback voltage VFB (VFB<VREF_{L}). When the output voltage is boosted so that the second reference voltage VREF_L becomes lower than or equal to the feedback voltage VFB (VFB≥VREF_{L}), the first enable signal may turn off the first pump circuit 21.

The first pump circuit 21 may adjust the output voltage under the control of the first enable signal. For example, when the target voltage is higher than the voltage currently formed at the output node N21 of the first amplifier 12, the voltage generating circuit 1 needs to boost the output voltage to reach the target voltage. In this case, the first pump circuit 21 may additionally apply a voltage to the output node N21 of the first amplifier 12 by supplying a current to the output node N21 of the first amplifier 12 in accordance with the control of the first enable signal so that the output voltage can be quickly boosted to the target voltage.

An output terminal of the second digital driving circuit 30 may be connected to the output node N21 of the first amplifier 12. The second digital driving circuit 30 may receive the feedback voltage VFB and a third reference voltage VREF_H and adjust the output voltage based on the feedback voltage VFB and the third reference voltage VREF_H. The second digital driving circuit 30 may include a second pump circuit 31 and a third amplifier 32. The third amplifier 32 may compare the feedback voltage VFB with the third reference voltage VREF_H. The third reference voltage VREF_H may be a voltage (VREF_{H}=VREF+Voffset2) added from the first reference voltage VREF by a second offset. The third amplifier 32 may output a second enable signal for controlling the second pump circuit 31. For example, the second enable signal may turn on or off the second pump circuit 31. In detail, the second enable signal may turn on the second pump circuit 31 while the third reference voltage VREF_H is lower than the feedback voltage (VFB>VREF_{H}), When the output voltage is stepped down so that the third reference voltage VREF_H becomes higher than or equal to the feedback voltage (VFB≤VREF_{H}), the second enable signal may turn off the second pump circuit 31.

The second pump circuit 31 may adjust the output voltage under the control of the second enable signal. For example, when the target voltage is lower than the voltage currently formed at the output node N21 of the first amplifier 12, the voltage generating circuit 1 has to step down the output voltage to reach the target voltage. In this case, the second pump circuit 31 may step down the voltage of the output node N21 of the first amplifier 12 by receiving (i.e., “sinking”) a current from the output node N21 of the first amplifier 12 under the control of the second enable signal so that the output voltage is quickly stepped down to the target voltage.

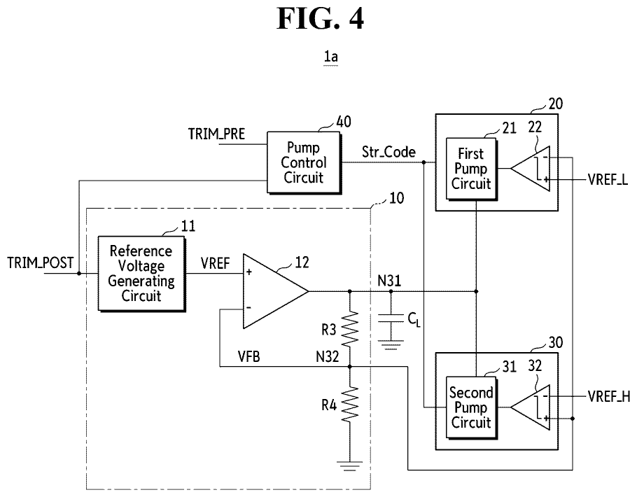

FIG. 4 is a circuit view illustrating a voltage generating circuit according to some embodiments. As shown, relative to the embodiment of FIG. 3, the voltage generating circuit 1a of FIG. 4 may further include a pump control circuit 40. The pump control circuit 40 may receive the first digital signal TRIM_POST and the second digital signal TRIM_PRE, and may output a pump control signal Str_Code for controlling the first pump circuit 21 and the second pump circuit 31 based on the first digital signal TRIM_POST and the second digital signal TRIM_PRE.

The first digital signal TRIM_POST may be an n-bit (n is a natural number) digital signal corresponding to a second operation subsequent to the first operation of the electronic device (e.g., the nonvolatile memory device) to which the voltage generating circuit 1a supplies a voltage. That is, the first digital signal TRIM_POST may be a digital signal for generating an output voltage required for the second operation of the electronic device. The second digital signal TRIM_PRE may be an n-bit digital signal corresponding to the first operation of the electronic device. That is, the second digital signal TRIM_PRE may be a digital signal for generating an output voltage required for the first operation of the electronic device. In a state that the output voltage generated by the second digital signal TRIM_PRE is formed at the output node N21 of the voltage generating circuit 1a, when the first digital signal TRIM_POST is provided to the voltage generating circuit 1a, the voltage generating circuit 1a may step down or boost the output voltage in accordance with the first digital signal TRIM_POST.

The pump control circuit 40 may adjust the boosting intensity or stepping-down intensity of the first pump circuit 21 or the second pump circuit 31 based on the first digital signal TRIM_POST and the second digital signal TRIM_PRE. For example, the pump control circuit 40 may adjust the boosting intensity or stepping-down intensity of the first pump circuit 21 or the second pump circuit 31 based on a value obtained by subtracting the second digital signal TRIM_POST from the first digital signal TRIM_PRE. A detailed method will be described later.

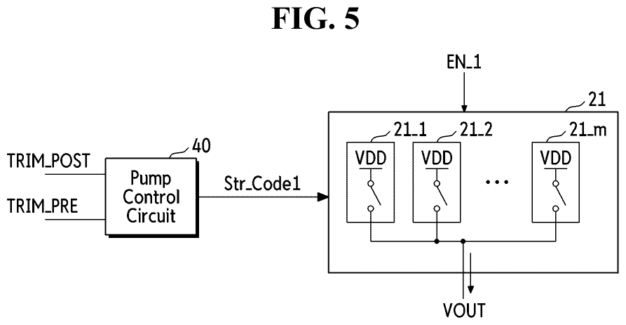

FIG. 5 is a block diagram illustrating an operation of a pump control circuit according to an embodiment of the invention. As shown, the first pump circuit 21 may include one or more boosting pumps 21_1 to 21_m (m is a natural number). The pump control circuit 40 may determine the number of boosting pumps to be turned on, among the one or more boosting pumps 21_1 to 21_m of the first pump circuit 21, based on the first digital signal TRIM_POST and the second digital signal TRIM_PRE. For example, the pump control circuit 40 may determine the number of boosting pumps to be turned on, among the one or more boosting pumps 21_1 to 21_m of the first pump circuit 21, based on a value obtained by subtracting the second digital signal TRIM_POST from the first digital signal TRIM_POST. That is, as a difference between the first digital signal TRIM_POST and the second digital signal TRIM_PRE is greater, the number of boosting pumps to be turned on may be greater. As the number of boosting pumps to be turned on is greater, the boosting intensity of the first pump circuit 21 may be greater. For example, as the number of boosting pumps to be turned on is greater, the current supplied by the first pump circuit 21 to the output node N21 of the first amplifier 12 may be greater. The first pump circuit 21 may receive a first pump control signal Str_Code1 from the pump control circuit 40, and may turn on some of the one or more boosting pumps 21_1 to 21_m in accordance with the first pump control signal Str_Code1.

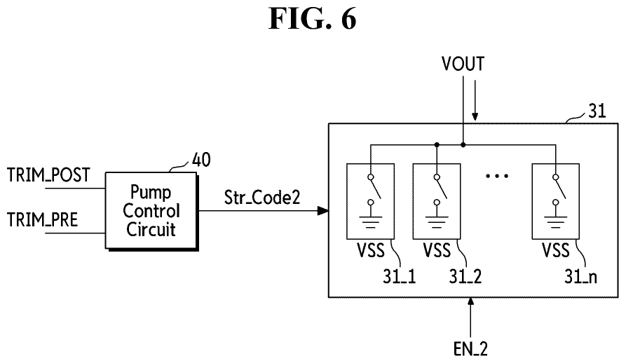

FIG. 6 is a block diagram illustrating an operation of a pump control circuit. As shown, the second pump circuit 31 may include one or more step-down pumps 31_1 to 31_n (n is a natural number). The pump control circuit 40 may determine the number of step-down pumps to be turned on, among the one or more step-down pumps 31_1 to 31_n of the second pump circuit 31, based on the first digital signal TRIM_POST and the second digital signal TRIM_PRE. For example, the pump control circuit 40 may determine the number of step-down pumps to be turned on, among the one or more step-down pumps 31_1 to 31_n of the second pump circuit 31, based on a value obtained by subtracting the second digital signal TRIM_PRE from the first digital signal TRIM_POST. That is, as the difference between the first digital signal TRIM_POST and the second digital signal TRIM_PRE is greater, the number of step-down pumps to be turned on may be greater. As the number of step-down pumps to be turned on is greater, the stepping-down intensity of the second pump circuit 31 may be stronger. For example, as the number of step-down pumps to be turned on is greater, the current provided by the second pump circuit 31 from the output node N21 of the first amplifier 12 may be greater. The second pump circuit 31 may receive a second pump control signal Str_Code2 from the pump control circuit 40, and may turn on some of the one or more step-down pumps 31_1 to 31_n in accordance with the second pump control signal Str_Code2.

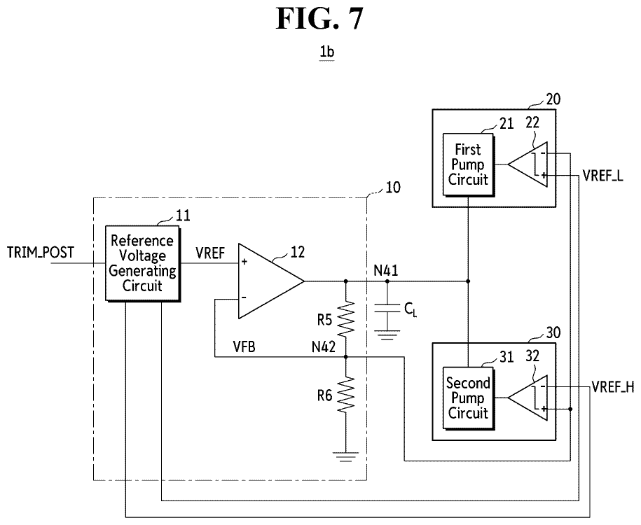

FIG. 7 is a circuit view illustrating a voltage generating circuit according to some embodiments. As shown, the reference voltage generating circuit 11 of a voltage generating circuit 1b may receive the first digital signal TRIM_POST to generate a first reference voltage VREF, a second reference voltage VREF_L obtained by being subtracted from the first reference voltage VREF by the first offset, and a third reference voltage VREF_H added to the first reference voltage VREF by the second offset. The reference voltage generating circuit 11 may provide the second reference voltage VREF_L and the third reference voltage VREF_H to the first digital driving circuit 20 and the second digital driving circuit 30, respectively.

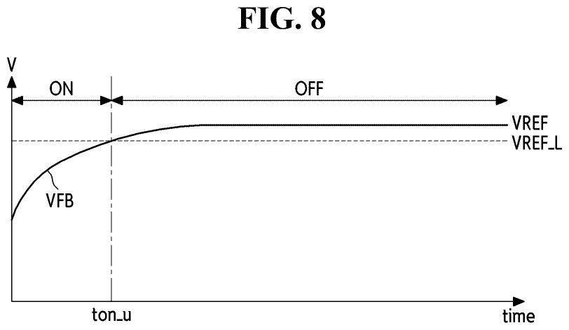

FIG. 8 is a graph illustrating a change in a feedback voltage of a voltage generating circuit according to some embodiments. As shown, the X-axis of the graph represents a change in time, whereas the Y-axis of the graph represents a change in the magnitude of a voltage. Referring to FIGS. 3 to 8, the feedback voltage VFB may be boosted by the voltage generating circuit 1 until the feedback voltage VFB reaches the first reference voltage VREF. Since the feedback voltage VFB is lower than the second reference voltage VREF_L during a period from t=0 (t is a time) to t=ton_u, the first enable signal may turn on the first pump circuit 21. Since the feedback voltage VFB is higher than the second reference voltage VREF_L after t=ton_u, the first enable signal may turn off the first pump circuit 21.

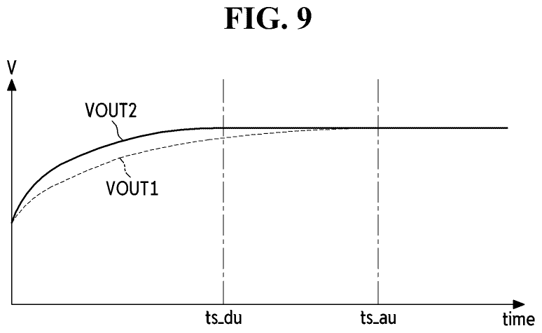

FIG. 9 is a graph illustrating a change in an output voltage of a voltage generating circuit according to some embodiments. X-axis of the graph represents a change in time, and Y-axis of the graph represents a change in the magnitude of a voltage. A first output voltage VOUT1 is an output voltage when the output voltage is boosted only by the analog voltage generating circuit 10 without using the first digital driving circuit 20, and a second output voltage VOUT2 is an output voltage when the output voltage is boosted using the analog voltage generating circuit 10 and the first digital driving circuit 20.

Referring to FIGS. 3 and 9, when the output voltage is boosted only by the analog voltage generating circuit 10, a time (stabilization time) for the first output voltage VOUT1 to reach the target voltage may be required from t=0 to t=ts_au. When the output voltage is boosted using the analog voltage generating circuit 10 and the first digital driving circuit 20, the stabilization time may be required from t=0 to t=ts_du. The first digital driving circuit 20 additionally applies a voltage to the output node N21 of the first amplifier 12 while the feedback voltage VFB is lower than the second reference voltage, whereby the stabilization time (from t=0 to t=ts_du) of the second output voltage VOUT2 may be faster than the stabilization time (from t=0 to t=ts_au) of the first output voltage VOUT1.

Since the first digital driving circuit 20 additionally applies a voltage to the output node N21 of the first amplifier 12 separately from the analog voltage generating circuit 10, the second output voltage VOUT2 may become unstable. For example, even after the second output voltage VOUT2 reaches the target voltage, a ripple in which the second output voltage VOUT2 shakes may occur. When the second output voltage VOUT2 is unstable, the stabilization time may be longer. That is, in order to reduce the stabilization time, it is necessary to suppress the occurrence of ripple of the second output voltage VOUT2.

According to some embodiments, when the feedback voltage VFB becomes higher than or equal to the second reference voltage, the first digital driving circuit 20 may turn off the first pump circuit 21 so that the first digital driving circuit 20 may boost the output voltage only by the analog voltage generating circuit 10 without additionally applying a voltage to the output node N21 of the first amplifier 12. As a result, a ripple occurring in the second output voltage VOUT2 may be minimized while the stabilization time of the second output voltage VOUT2 is reduced.

The first digital driving circuit 20 may additionally apply a voltage to the output node N21 of the first amplifier 12 while the feedback voltage VFB is lower than the second reference voltage VREF_L. In this case, when the voltage is applied too less, it may take a long time for the output voltage to reach the target voltage. On the contrary, when the voltage is applied too much, it may take a shorter time for the output voltage to reach the target voltage, but an overrun or the like in which the output voltage is higher than the target voltage instantaneously may occur, whereby the output voltage may become unstable. As a result, when the first digital driving circuit 20 additionally applies a voltage to the output node N21 of the first amplifier 12, too less voltage or too much voltage may cause a long stabilization time.

As described above, the first digital signal TRIM_POST may be an n-bit digital signal (n is a natural number) for generating an output voltage required for the second operation of the electronic device, which corresponds to the second operation subsequent to the first operation of the electronic device (e.g., the nonvolatile memory device) to which the voltage generating circuit 1 supplies a voltage. The second digital signal TRIM_PRE may be an n-bit digital signal for generating an output voltage required for the first operation of the electronic device, which corresponds to the first operation of the electronic device. For example, when the difference between the first digital signal TRIM_POST and the second digital signal TRIM_PRE is great, the difference between the output voltage corresponding to the first digital signal TRIM_POST and the output voltage corresponding to the second digital signal TRIM_PRE may be great. Accordingly, when the difference between the first digital signal TRIM_POST and the second digital signal TRIM_PRE is great, the boosting intensity of the first pump circuit 21 should be strong, and when the difference between the first digital signal TRIM_POST and the second digital signal TRIM_PRE is small, the boosting intensity of the first pump circuit 21 should be weak.

According to some embodiments, the pump control circuit 40 may determine the number of boosting pumps to be turned on, among the one or more boosting pumps of the first pump circuit 21, based on the first digital signal TRIM_POST and the second digital signal TRIM_PRE. In more detail, the pump control circuit 40 may determine the number of boosting pumps to be turned on, among the one or more boosting pumps of the first pump circuit 21, based on a value obtained by subtracting the second digital signal TRIM_POST from the first digital signal TRIM_POST. That is, the pump control circuit 40 adjusts the boosting intensity of the first pump circuit 21 based on the first digital signal TRIM_POST and the second digital signal TRIM_PRE so that the first digital driving circuit 20 may apply an appropriate additional voltage to the output node N21 of the first amplifier 12 while the feedback voltage VFB is lower than the second reference voltage.

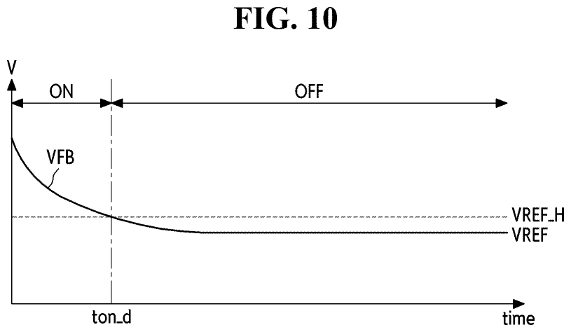

FIG. 10 is a graph illustrating a change in a feedback voltage of a voltage generating circuit according to some embodiments. As shown, the X-axis of the graph represents a change in time, whereas the Y-axis of the graph represents a change in the magnitude of a voltage. Referring to FIGS. 3 to 7 and 10, the feedback voltage VFB may be stepped down by the voltage generating circuit 1 until it reaches the first reference voltage VREF. Since the feedback voltage VFB is higher than the third reference voltage VREF_H during a period from t=0 to t=ton_d, the second enable signal may turn on the second pump circuit 31. Since the feedback voltage VFB is lower than the second reference voltage VREF_L after t=ton_d, the second enable signal may turn off the second pump circuit 31.

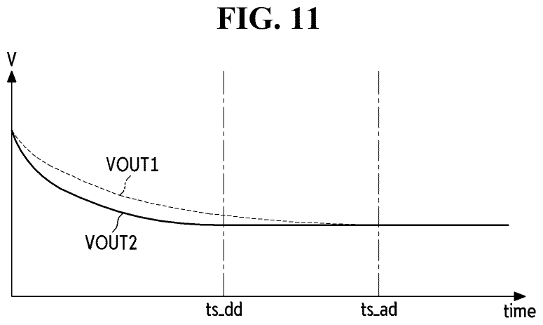

FIG. 11 is a graph illustrating a change in an output voltage of a voltage generating circuit according to some embodiments. The X-axis of the graph represents a change in time, and the Y-axis of the graph represents a change in the magnitude of a voltage. A third output voltage VOUT1 is an output voltage when the output voltage is stepped down only by the analog voltage generating circuit 10 without using the second digital driving circuit 30, and a fourth output voltage VOUT2 is an output voltage when the output voltage is stepped down using the analog voltage generating circuit 10 and the second digital driving circuit 30.

Referring to FIGS. 3 to 7 and 11, when the output voltage is stepped down only by the analog voltage generating circuit 10, a time (stabilization time) for the third output voltage VOUT1 to reach the target voltage may be required from t=0 to t=ts_ad. When the output voltage is stepped down using the analog voltage generating circuit 10 and the second digital driving circuit 30, the stabilization time may be required from t=0 to t=ts_dd. The second digital driving circuit 30 steps down the voltage of the output node N21 of the first amplifier 12 while the feedback voltage VFB is higher than the third reference voltage, whereby the stabilization time (from t=0 to t=ts_dd) of the fourth output voltage VOUT2 may be faster than the stabilization time (from t=0 to t=ts_ad) of the third output voltage VOUT1.

Since the second digital driving circuit 30 additionally steps down the voltage of the output node N21 of the first amplifier 12 separately from the analog voltage generating circuit 10, the fourth output voltage VOUT2 may become unstable. For example, even after the fourth output voltage VOUT2 reaches the target voltage, a ripple in which the fourth output voltage VOUT2 shakes may occur. When the fourth output voltage VOUT2 is unstable, the stabilization time may be longer. That is, in order to reduce the stabilization time, it is necessary to suppress the occurrence of ripple of the fourth output voltage VOUT2.

According to some embodiments, when the feedback voltage VFB becomes lower than or equal to the third reference voltage, the second digital driving circuit 30 may turn off the second pump circuit 31 so that the second digital driving circuit 30 may step down the output voltage only by the analog voltage generating circuit 10 without additionally reducing the voltage of the output node N21 of the first amplifier 12. As a result, the ripple occurring in the fourth output voltage VOUT2 may be minimized while the stabilization time of the fourth output voltage VOUT2 is reduced.

The second digital driving circuit 30 may additionally step down the voltage of the output node N21 of the first amplifier 12 while the feedback voltage VFB is higher than the third reference voltage. In this case, when the voltage is stepped down too less, it may take a long time for the output voltage to reach the target voltage. On the contrary, when the voltage is stepped down too much, it may take a shorter time for the output voltage to reach the target voltage, but an overrun or the like in which the output voltage is lower than the target voltage instantaneously may occur, whereby the output voltage may become unstable. As a result, when the second digital driving circuit 30 steps down the voltage of the output node N21 of the first amplifier 12 while the feedback voltage VFB is higher than the third reference voltage VREF_H, too less voltage or too much voltage may cause a long stabilization time.

As described above, as the difference between the first digital signal TRIM_POST and the second digital signal TRIM_PRE is greater, the stepping-down intensity of the second pump circuit 31 should be strong, and as the difference between the first digital signal TRIM_POST and the second digital signal TRIM_PRE is smaller, the stepping-down intensity of the second pump circuit 31 should be weak.

According to some embodiments, the pump control circuit 40 may determine the number of step-down pumps to be turned on, among the one or more step-down pumps of the second pump circuit 31, based on the first digital signal TRIM_POST and the second digital signal TRIM_PRE. In more detail, the pump control circuit 40 may determine the number of step-down pumps to be turned on, among the one or more step-down pumps of the second pump circuit 31, based on a value obtained by subtracting the second digital signal TRIM_POST from the first digital signal TRIM_POST. That is, the pump control circuit 40 adjusts the stepping-down intensity of the second pump circuit 31 based on the first digital signal TRIM_POST and the second digital signal TRIM_PRE so that the second digital driving circuit 30 may step down an appropriate voltage when further reducing the voltage of the output node N21 of the first amplifier 12 while the feedback voltage VFB is higher than the third reference voltage VREF_H.

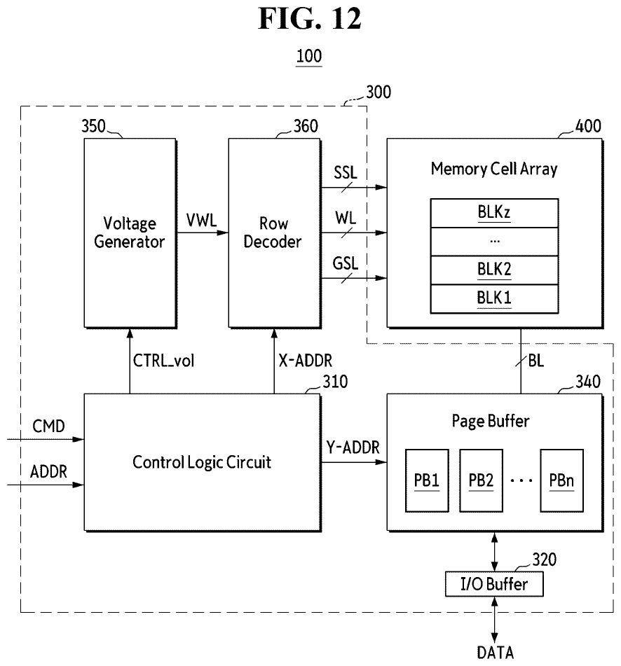

FIG. 12 is a block diagram illustrating a nonvolatile memory device to which a voltage generating circuit according to some embodiments is applied. As shown, the nonvolatile memory device 100 includes a memory cell array 400 and a peripheral circuit unit 300 connected to the memory cell array 400. The peripheral circuit unit 300 may include a voltage generator 350, a row decoder 360, a page buffer 340, an input/output circuit 320, and a control logic circuit 310. The memory cell array 400 may include a plurality of memory blocks BLK1 to BLKz. Each of the plurality of memory blocks BLK1 to BLKz may be connected to the row decoder 360 through a word line WL, a string selection line SSL and a ground selection line GSL, and may be connected to the page buffer 340 through a bit line BL.

The memory cell array 400 may include a plurality of memory cells disposed in regions where a plurality of word lines WL and a plurality of bit lines BL cross each other. Each of the memory cells may be formed in various cell types including a single level cell (SLC), a multi level cell (MLC), a triple level cell (TLC), a quad level cell (QLC), and the like.

The control logic circuit 310 may receive a command CMD and an address ADDR to generate a control signal CTRL_vol for controlling the voltage generator 350 and a control signal for controlling the page buffer 340, and may generate a row address X_ADDR and a column address Y_ADDR based on the address ADDR. The control logic circuit 310 may output the row address X_ADDR to the row decoder 360 and output the column address Y_ADDR to the input/output circuit 320.

The voltage generator 350 may receive power PWR, regulate a word line basic voltage VWL for a memory operation in accordance with the control signal CTRL_vol from the control logic circuit 310 and provide the word line basic voltage VWL to the memory cell array 400 through the row decoder 360.

The row decoder 360 may be connected to the memory cell array 400 through the word line WL, the string selection line SSL and the ground selection line GSL. The row decoder 360 may decode the row address X_ADDR input from the control logic circuit 310 to select at least one of the plurality of memory blocks BLK1 to BLKz. That is, the row decoder 360 may select the word line WL, the string selection line SSL and the ground selection line GSL by using the row address X_ADDR. The row decoder 360 may provide the word line basic voltage VWL supplied from the voltage generator 350 to the word line WL.

The page buffer 340 may be connected to the memory cell array 400 through the bit line BL, and may be connected to the input/output circuit 320 through the bit line BL. During a program operation, the input/output circuit 320 may receive program data provided from a memory controller, and may provide the program data DATA to the page buffer 340 based on the column address Y_ADDR provided from the control logic circuit 310. During a read operation, the input/output circuit 320 may provide the read data DATA stored in the page buffer 340 to the outside (e.g., the memory controller) based on the column address Y_ADDR provided from the control logic circuit 310.

The control logic circuit 310 may control the overall operation of the nonvolatile memory device 100 and output each control signal related to the memory operation. For example, the control logic circuit 310 may control the nonvolatile memory device 100 by using an internal control signal based on at least one of the address ADDR, the command CMD or the control signal CTRL, which is received from the memory controller.

According to some embodiments, the voltage generator 350 may include the voltage generating circuit described with reference to FIGS. 3 to 11. The voltage generating circuit may include an analog voltage generating circuit, first and second digital driving circuits, and a pump control circuit. The voltage generator 350 may receive a first digital signal corresponding to a second operation subsequent to a first operation of the memory cell array 400 and a second digital signal corresponding to the first operation from the control logic circuit 310. The voltage generator 350 may generate an output voltage based on the first digital signal by using the received power PWR. The generated output voltage may be a word line basic voltage VWL. When the generated output voltage is the word line basic voltage VWL, the capacitive load present at an output terminal of the voltage generating circuit may be the capacitive load present at the word line. The operations of the analog voltage generating circuit, the first and second digital driving circuits and the pump control circuit have been described as above and thus will be omitted herein.

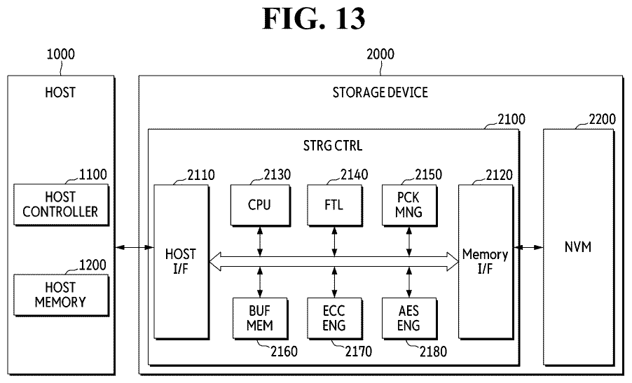

FIG. 13 is a block diagram illustrating a storage device that includes the nonvolatile memory device of FIG. 12. As shown, a host-storage system may include a host 1000 and a storage device 2000; the storage device 2000 may also include a storage controller 210 and a nonvolatile memory (NVM) 2200. Also, the host 1000 may include a host controller 1100 and a host memory 1200. The host memory 1200 may serve as a buffer memory for temporarily storing data to be transmitted to the storage device 2000 or data transmitted from the storage device 2000.

The storage device 2000 may include storage media for storing data in accordance with a request from the host 1000. As an example, the storage device 2000 may include at least one of a solid state drive (SSD), an embedded memory, or a detachable external memory. When the storage device 2000 is the SSD, the storage device 2000 may be a device that complies with the standard of a nonvolatile memory express (NVMe). When the storage device 2000 is the embedded memory or the external memory, the storage device 2000 may be a device that complies with the standard of a universal flash storage (UFS) or an embedded multi-media card (eMMC). Each of the host 1000 and the storage device 2000 may generate and transmit packets according to a standard protocol that is employed.

When the nonvolatile memory 2200 of the storage device 2000 includes a flash memory, the flash memory may include a 2D NAND memory array or a 3D (or vertical) NAND (VNAND) memory array. As another example, the storage device 2000 may include other various types of nonvolatile memories. For example, a magnetic random access memory (MRAM), a spin-transfer torque MRAM, a Conductive Bridging RAM (CBRAM), a Ferroelectric RAM (FeRAM), a Phase RAM (PRAM), a Resistive RAM and other various types of memories may be applied to the storage device 2000.

Each of the host controller 1100 and the host memory 1200 may be implemented as a separate semiconductor chip. Alternatively, the host controller 1100 and the host memory 1200 may be integrated into the same semiconductor chip. As an example, the host controller 1100 may be any of a plurality of modules provided in an application processor, and the application processor may be implemented as a system on chip (SoC). In addition, the host memory 1200 may be an embedded memory provided in the application processor, or may be a nonvolatile memory or memory module disposed outside the application processor.

The host controller 1100 may store data (e.g., write data) of a buffer region in the nonvolatile memory 2200, or may manage an operation of storing data (e.g., read data) of the nonvolatile memory 2200 in the buffer region. The storage controller 2100 may include a host interface 2110, a storage-memory interface 2120 and a central processing unit (CPU) 2130. The storage controller 2100 may further include a flash translation layer (FTL) 2140, a package manger 2150, a buffer memory 2160, an error correction code (ECC) engine 2170 and an advanced encryption standard (AES) engine 2180. The storage controller 2100 may further include a working memory (not shown) in which the flash translation layer (FTL) 2140 is loaded, and the CPU 2130 may control data write and read operations for the nonvolatile memory device (NVM) 2200 by executing the flash translation layer 2140.

In detail, the storage device 2000 may receive a storage device driving signal from the host 1000 through the host interface 2110. The CPU 2130 may transmit an initialization command in response to the storage device driving signal. The initialization command may be transmitted to the nonvolatile memory device 2200 through the storage-memory interface 2120.

The host interface 2110 may transmit and receive packets to and from the host 1000. The packets transmitted from the host 1000 to the host interface 2110 may include a command or data to be written in the nonvolatile memory device 2200, and the packets transmitted from the host interface 2110 to the host 1000 may include a response to the command or data read from the nonvolatile memory device 2200. The storage-memory interface 2120 may transmit the data to be written in the nonvolatile memory device 2200 to the nonvolatile memory device 2200 or may receive the data read from the nonvolatile memory device 2200. Such a storage-memory interface 2120 may be implemented to comply with standard protocols such as Toggle or Open NAND Flash Interface (ONFI).

The flash translation layer 2140 may perform various functions such as address mapping, wear-leveling and garbage collection. The address mapping operation is an operation of changing a logical address received from the host 1000 to a physical address used to actually store data in the nonvolatile memory device 2200. The wear-leveling is a technique for preventing excessive degradation of a specific block by allowing blocks in the nonvolatile memory device 2200 to be used uniformly, and may be exemplarily implemented through firmware technology for balancing erase counts of physical blocks. The garbage collection is a technique for making sure of the available capacity in the nonvolatile memory device 2200 by copying valid data of a block to a new block and then erasing the existing block.

The packet manger 2150 may generate packets according to a protocol of an interface negotiated with the host 1000 or parse various kinds of information from the packets received from the host 1000. Also, the buffer memory 2160 may temporarily store data to be written in the nonvolatile memory device 2200 or data to be read from the nonvolatile memory device 2200. The buffer memory 2160 may be provided in the storage controller 2100, but may be disposed outside the storage controller 2100.

The ECC engine 2170 may perform error detection and correction functions for the read data read from the nonvolatile memory device 2200. In more detail, the ECC engine 2170 may generate parity bits for write data to be written in the nonvolatile memory device 2200, and the generated parity bits may be stored in the nonvolatile memory device 2200 together with the write data. When reading the data from the nonvolatile memory device 2200, the ECC engine 2170 may correct an error of the read data by using the parity bits read from the nonvolatile memory device 2200 together with the read data, and then may output the error-corrected read data.

The AES engine 2180 may perform at least one of an encryption operation or a decryption operation for the data input to the storage controller 2100 by using a symmetric-key algorithm. According to some embodiments, a portion of the nonvolatile memory device (NVM) 2200 may be implemented as the above-described nonvolatile memory device (100 of FIG. 12). For example, the nonvolatile memory device (NVM) 2200 may include one or more nonvolatile memory devices (100 of FIG. 12). The storage controller 2100 may request the nonvolatile memory device (NVM) 2200 to perform a first operation for writing, reading or erasing data. In addition, the storage controller 2100 may request the nonvolatile memory device (NVM) 2200 to perform a second operation for writing, reading or erasing data subsequently to the first operation. The nonvolatile memory device (NVM) 2200 may receive a request to perform the second operation to generate an output voltage required for the second operation. The operation of the nonvolatile memory device (100 of FIG. 12) implemented as a portion of the NVM 2200 has been described as above, and thus will be omitted herein.

Although some embodiments of the present disclosure have been described above with reference to the accompanying diagrams, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

1. A voltage generating circuit, comprising:
an analog voltage generating circuit having a first amplifier therein, which is configured to generate an output voltage in response to a first reference voltage and a feedback voltage;
a first digital driving circuit configured to selectively provide a pull-up voltage boost to the output voltage generated by the first amplifier, in response to comparing the feedback voltage to a second reference voltage having a magnitude less than the first reference voltage by a first offset voltage; and
a second digital driving circuit configured to selectively provide a pull-down voltage boost to the output voltage generated by the first amplifier, in response to comparing the feedback voltage to a third reference voltage having a magnitude greater than the first reference voltage by a second offset voltage.

2. The voltage generating circuit of claim 1,
wherein the first digital driving circuit includes:
an amplifier configured to generate a first enable signal in response to comparing the feedback voltage to the second reference voltage; and
a first pump circuit configured to selectively pull-up the output voltage in response to the first enable signal; and
wherein the second digital driving circuit includes:
an amplifier configured to generate a second enable signal in response to comparing the feedback voltage to the third reference voltage; and
a second pump circuit configured to selectively pull-down the output voltage in response to the second enable signal.

3. The volage generating circuit of claim 2, further comprising:
a pump control circuit configured to control the first pump circuit;
wherein the first pump circuit includes one or more boosting pumps; and
wherein the pump control circuit is configured to output a first pump control signal, which determines a number of boosting pumps to be turned on among the one or more boosting pumps, based on first and second digital signals.

4. The voltage generating circuit of claim 2, further comprising:
a pump control circuit configured to control the second pump circuit;
wherein the second pump circuit includes one or more step-down pumps; and
wherein the pump control circuit is configured to output a second pump control signal, which determines a number of step-down pumps to be turned on among the one or more step-down pumps, based on the first and second digital signals.

5. The voltage generating circuit of claim 2, wherein the first enable signal is configured to turn on the first pump circuit when the second reference voltage is greater than the feedback voltage, and turn off the first pump circuit when the second reference voltage is less than the feedback voltage.

6. The voltage generating circuit of claim 5, wherein the second enable signal is configured to turn on the second pump circuit when the third reference voltage is less than the feedback voltage, and turn off the second pump circuit when the third reference voltage is greater than the feedback voltage.

7. The voltage generating circuit of claim 1, wherein the analog voltage generating circuit further includes a reference voltage generating circuit configured to generate the first reference voltage based on the first digital signal.

8. The voltage generating circuit of claim 7, wherein the reference voltage generating circuit is configured to generate the second and third reference voltages based on the first reference voltage.

9. A voltage generating circuit comprising:
a reference voltage generating circuit configured to receive a first digital signal and generate a first reference voltage based on the first digital signal;
a first amplifier configured to receive the first reference voltage and a feedback voltage and generate an output voltage;
a first digital driving circuit configured to compare the feedback voltage with a second reference voltage subtracted from the first reference voltage by a first offset and increase the output voltage in accordance with the compared result; and
a pump control circuit configured to adjust increasing intensity of the first digital driving circuit based on the first digital signal and a second digital signal.

10. The voltage generating circuit of claim 9,
wherein the first digital driving circuit includes one or more boosting pumps configured to increase the output voltage in accordance with the compared result of the feedback voltage and the second reference voltage; and
wherein the pump control circuit is configured to output a first pump control signal that determines the number of boosting pumps to be turned on, among the one or more boosting pumps, based on the first and second digital signals.

11. The voltage generating circuit of claim 10, wherein the pump control circuit is configured to output a first pump control signal that determines the number of boosting pumps to be turned on, among the one or more boosting pumps, based on a value obtained by subtracting the second digital signal having n bits (n is a natural number) from the first digital signal having n bits.

12. The voltage generating circuit of claim 9, wherein the first digital driving circuit includes a second amplifier configured to compare the second reference voltage with the feedback voltage and output a first enable signal based on the compared result, and a first pump circuit configured to boost the output voltage in accordance with the first enable signal.

13. The voltage generating circuit of claim 12, wherein the first enable signal is configured to turn on the first pump circuit while the second reference voltage is higher than the feedback voltage, and turn off the first pump circuit while the second reference voltage is lower than or equal to the feedback voltage.

14. The voltage generating circuit of claim 9, further comprising a second digital driving circuit configured to compare the feedback voltage with a third reference voltage added to the first reference voltage by a second offset and decrease the output voltage in accordance with the compared result.

15. The voltage generating circuit of claim 9, wherein the reference voltage generating circuit is configured to generate the second and third reference voltages based on the first reference voltage.

16. A nonvolatile memory device, comprising:
a memory cell array including a plurality of memory cells for storing data;
a control logic circuit for controlling the memory cell array; and
a voltage generator including an analog voltage generating circuit configured to generate a voltage required for an operation of the memory cell array and a first digital driving circuit configured to adjust an output voltage of the analog voltage generating circuit;
wherein the control logic circuit is configured to provide the voltage generator with a first digital signal corresponding to a second operation subsequent to a first operation of the memory cell array;
wherein the analog voltage generating circuit is configured to provide the memory cell array with an output voltage required for the second operation based on a first reference voltage corresponding to the first digital signal and a feedback voltage; and
wherein the first digital driving circuit is configured to compare a second reference voltage subtracted from the first reference voltage by a first offset with the feedback voltage, and increase the output voltage in accordance with the compared result.

17. The nonvolatile memory device of claim 16,
wherein the voltage generator further includes a pump control circuit configured to adjust an increasing intensity of the first digital driving circuit;
wherein the first digital driving circuit includes one or more boosting pumps configured to increase the output voltage in accordance with the compared result of the second reference voltage and the feedback voltage; and
wherein the pump control circuit is configured to output a first pump control signal that determines the number of boosting pumps to be turned on, among the one or more boosting pumps, based on the first digital signal and a second digital signal corresponding to the first operation.

18. The nonvolatile memory device of claim 17, wherein the pump control circuit is configured to output the first pump control signal based on a value obtained by subtracting the second digital signal having n bits (n is a natural number) from the first digital signal having n bits.

19. The nonvolatile memory device of claim 16, wherein the first digital driving circuit is configured to increase the output voltage while the second reference voltage is higher than the feedback voltage, and does not increase the output voltage while the second reference voltage is lower than or equal to the feedback voltage.

20. The nonvolatile memory device of claim 16,
wherein the voltage generator further includes a second digital driving circuit configured to adjust the output voltage of the analog voltage generating circuit; and
wherein the second digital driving circuit is configured to compare a third reference voltage added to the first reference voltage by a second offset with the feedback voltage and decrease the output voltage in accordance with the compared result.

21-22. (canceled)
